(19) United States
(12) Patent Application Publication
(10) Pub. No.: US 2004/0124513 A1
(43) Pub. Date: Jul. 1, 2004

(54) High-density multichip module package

(75) Inventors: Kwun Yao Ho, Taipei (TW); Moriss Kung, Taipei (TW)

Correspondence Address: ARENT FOX KINTNER PLOTKIN & KAHN, PLLC, Suite 400, 1050 Connecticut Avenue, Washington, DC, 20036-5339, US

(73) Assignee: VIA Technologies, Inc.

(21) Appl. No.: 10/734,195

(22) Filed: Dec. 15, 2003

(30) Foreign Application Priority Data
Dec. 19, 2002 (TW) 091136733

(51) Int. Cl. H01L 21/44; H01L 23/02; H01L 29/40

(52) U.S. Cl. 257/678; 438/106; 438/107; 257/734

(57) ABSTRACT

The invention discloses a high-density multi-chip module package which can integrates active and passive devices stacked by a three-dimensional face-to-back interconnection. The multichip module package of the invention at least comprises a multichip module substrate which has an semiconductor substrate, an insulating layer on the semiconductor substrate, a multilayer interconnection structure on the insulating layer, and a plurality of conductive plugs penetrating the semiconductor substrate and the insulating layer to provide electric connection with the multilayer interconnection structure; and a plurality of chips disposing on the semiconductor substrate and electrically connecting to the multilayer interconnection structure through the conductive plugs.

### BACKGROUND OF THE INVENTION

1. Field of the Invention

The present invention relates to a multi-chip module (MCM) package, and more particularly to a high density multi-chip module package which can integrates active and passive devices stacked by a three-dimensional face-to-back interconnection.

2. Description of the Related Art

Integrated circuit (IC) package technologies are continually developed toward demands of small size and high integration in the integrated circuit industrial sector. The improvements focus on the integration of millions of transistors, devices and circuits on a silicon substrate.

Through a serious of precise and fine-tune processes such as etching, implantation, deposition and dicing in various processing equipments, integrated circuits are formed on wafers. Each processed wafer includes a plurality of chips, and each chip can be packaged by a surrounding molding compound and electrically connect to outside via pins. Package examples include a M dual-in-line package( M-dip )having two rows of pins connecting the chip and a printed circuit board ( PCB ) through the bottom of the package structure. Other package examples for high density PCB include a single-in-line package (SIP) and a small outline J-leaded package ( SOJ)

Integrated circuit package can be sorted by chip number in a package assembly. A single chip package( SCP )and a multichip package (MCP) are two major sorts and the MCP includes a multichip module (MCM) . Integrated circuit package can also be sorted by mounting types which comprise a pin-through-hole (PTH) type and a surface mount technology ( SMT) . The pins of the PTH type could be fine pins or thin metal plates. The fine pins or the thin metal plates are inserted into pin holes of a socket or a PCB when the chip is mounted. Chips with SMT packages are adhered on a PCB and then are soldered during mounting. In order to reduce the volume of an integrated circuit package and increase the integration of the chip, a more advanced direct chip attach (DCA) package is applied. The DCA package technology mounts an integrated circuit chip on a substrate directly and then completes the electrical connection.

Referring to FIG. 1, a conventional package structure with multiple chips on a package substrate is shown. The chips 10 could be mounted on a substrate 30 through a plurality of bumps 20 by flip chip packaging. The chips 10 could also be mounted on the substrate 30 and connected through bonding wires 35. A molding compound 40 is then applied on the chips 10 and the substrate 30 to protect and cover the chips 10.

In the conventional package technologies mentioned above, chips are mounted on a substrate directly or indirectly and electrically connected to each other by circuit routing in the substrate which could increase the difficulty of substrate circuit routing. Furthermore, the substrate circuit routing increases the distance between chips as well, and the size of integrated circuit package is also enlarged so as to raise the cost of substrate. Moreover, the long path of circuit routing would further limit the electrical performance of integrated circuit package. Although silicon on a chip (SOC) technology which integrates active devices and passive devices on one chip is developed to resolve the issues set forth, design and process difficulties as well as high cost still are obstacles to be broke through.

### SUMMARY OF THE INVENTION

It is therefore an object of the invention to provide a high-density multi-chip module package structure and manufacturing method thereof to increase the layout density and decrease the package size and to integrate active and passive devices by simply processes.

To achieve the above object, and in accordance with the purpose of the invention, the multichip module package of the invention at least comprises a multichip module substrate which has a semiconductor substrate, an insulating layer on the semiconductor substrate, a multilayer interconnection structure on the insulating layer, and a plurality of conductive plugs penetrating the semiconductor substrate and the insulating layer to provide electric connection with the multilayer interconnection structure; and a plurality of chips disposing on the semiconductor substrate and electrically connecting to the multilayer interconnection structure through the conductive plugs.

It is to be understood that both the foregoing general description and the following detailed description are exemplary and explanatory only and are not restrictive of the invention, as claimed.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 shows a conventional package structure with multiple chips on a package substrate;

FIGS. 2-6 show a manufacturing flow of forming a miltichip module package according to a first embodiment of this invention; and

FIG. 7 shows a miltichip module package structure according to a second embodiment of this invention.

### DESCRIPTION OF THE PREFERRED EMBODIMENT

It is to be understood and appreciated that the process steps and structures described below do not cover a complete process flow and structures. The present invention can be practiced in conjunction with various fabrication techniques that are used in the art, and only so much of the commonly practiced process steps are included herein as are necessary to provide an understanding of the present invention.

The present invention will be described in detail with reference to the accompanying drawings. It should be noted that the drawings are in greatly simplified form and they are not drawn to scale. Moreover, dimensions have been exaggerated in order to provide a clear illustration and understanding of the present invention.

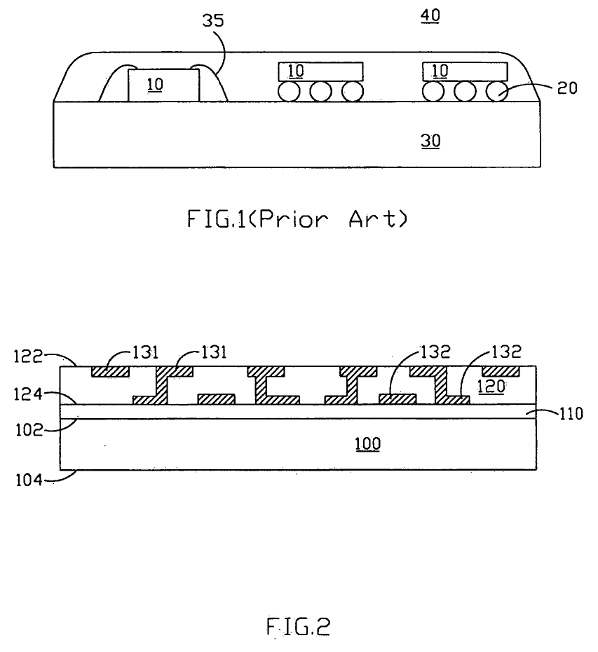

The invention provides a high-density multi-chip module package and the manufacturing method thereof which forms a plurality of conductive plugs in an integrated circuit substrate to electrically connect a plurality of chips and increase chip density and decrease the size of the package structure. FIGS. 2-6 show a manufacturing flow of forming a miltichip module package according to a first embodiment of this invention. First of all, referring to FIG. 2, a semiconductor substrate 100 is provided and an insulating layer 110 is formed on a first surface 102 of the semiconductor substrate 100, wherein the semiconductor substrate 100 can be a silicon substrate. Next, a multilayer interconnection structure 120 with at least one integrated circuit device is formed on the insulating layer 110. The multilayer interconnection structure 120 has a plurality of first bonding pads 131 and second bonding pads 132 formed respectively on a first surface 122 and a second surface 124 of the multilayer interconnection structure 120. Then a grinding and polishing process is performed to remove a portion of the semiconductor substrate 100 from a second surface 104 of the semiconductor substrate 100 so as to reduce the thickness of the semiconductor substrate 100. The thickness of the semiconductor substrate 100 is about 10 micron meter to about 500 micron meter after the grinding and polishing process. The grinding and polishing process preferably comprises a chemical mechanical polishing process.

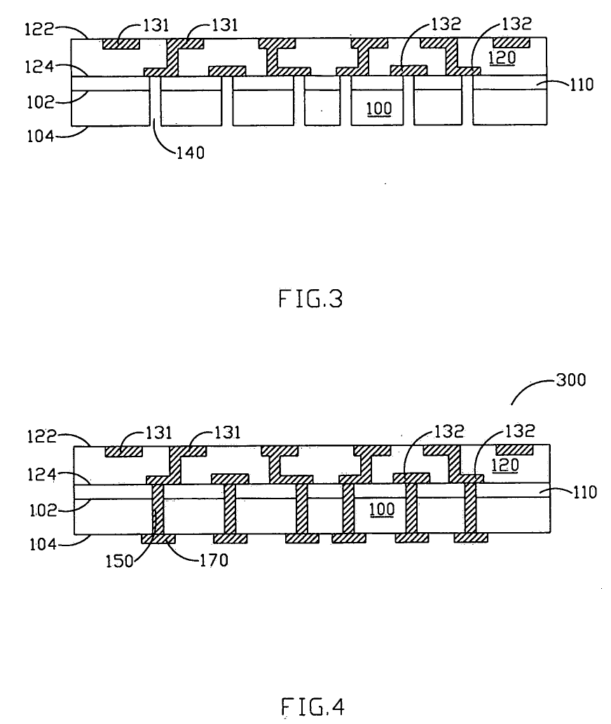

Referring to FIG. 3, an etching process is performed on the second surface 104 of the semiconductor substrate 100 to remove a portion of the semiconductor substrate 100 and a portion of the insulating layer 110 so as to form a plurality of via holes 140 penetrating the semiconductor substrate 100 and the insulating layer 110, and expose the second bonding pads 132. During the etching process, a first photoresist layer can be formed on the second surface 104 firstly (nor shown). Then the etching process is performed by using ion beam etching, reactive ion etching, chemical etching, laser enhanced etching, ultraviolet enhanced etching or electrochemical etching to remove a portion of the semiconductor substrate 100 and a portion of the insulating layer 110. Finally, the first photoresist layer is removed.

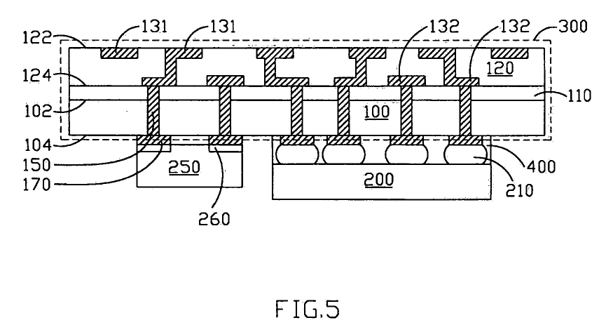

Referring to FIG. 4, a conductive material is filled into the via holes 140 to form conductive plugs 150 with metal pads 170. The conductive material comprises tungsten or copper, but other metal should not be excluded. Furthermore, the conductive material can be also a conductive paste. These conductive plugs 150 can electrically connect the multilayer interconnection structure 120 and other device to make signals transmit therebetween. After the conductive plugs 150 are formed, a third photoresist layer (not shown) can be formed and patterned on the second surface 104 of the semiconductor substrate, and third bonding pads 170 are formed on the conductive plugs 150. Finally, the third photoresist layer is removed, and a high-density multichip module substrate 300 of this invention is formed, wherein the multichip module substrate 300 is an integrated circuit chip with a plurality of conductive plugs in its backside. The third bonding pads 170 are used to electrically connect with other devices.

Referring to FIG. 5, a plurality of chips are mounted and electrically connected to the third bonding pads to complete a flip chip package structure. The chips comprise at least one active chip 200 and at least one passive chip 250. The active chip 200 comprises a flip chip having a plurality of first bumps 210. The active chip is electrically connected to the multichip module substrate 300 through the bonding between the first bumps 210 and the third bonding pads 170. The passive chip 250 comprises a plurality of electrodes 260. The passive chip 250 is electrically connected to the multichip module substrate 300 through the bonding between the electrodes 260 and the third bonding pads 170. Then a flip chip package process is performed to fill an underfill material 400 between the active chip 200 and the substrate 300 to protect the joints between the chips and the substrate such that the high-density multichip module structure of the invention is finished. Since the passive chip can be designed and arranged adjacent the active chip in the high-density multichip module structure of the invention, the electrical performance of the integrated circuit package structure can be improved. Because the chips are modular packaged, signals between chips are not transmitted via circuits on a package substrate so that the size of package structure can be reduced and the performance of package can be upgraded. The application of the high-density multichip module package structure is not limited to the description set forth and described below, and it depends on demands of product and production process.

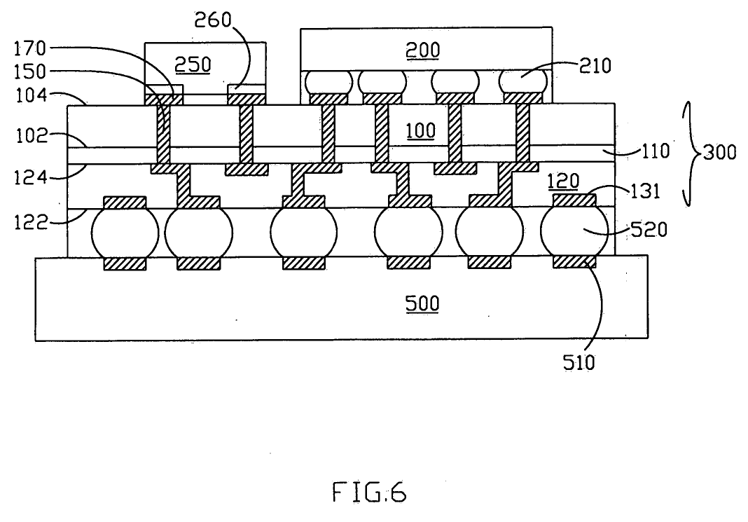

Referring to FIG. 6, the high-density multichip module structure is bonded to a package substrate. First of all, a package substrate 500 having a plurality of fourth bonding pads 510 is provided. Next a plurality of second bumps 520 are bonded to the first bonding pads 131 on the first surface 122 of the multilayer interconnection structure. Finally, the high-density multichip module structure is bonded to a package substrate 500 through the bonding between the second bumps 520 and the fourth bonding pads 510 by a flip chip process. The multichip module structure shown in FIG. 6 is one embodiment which has the-passive chip 250, the active chips 200 and 300.

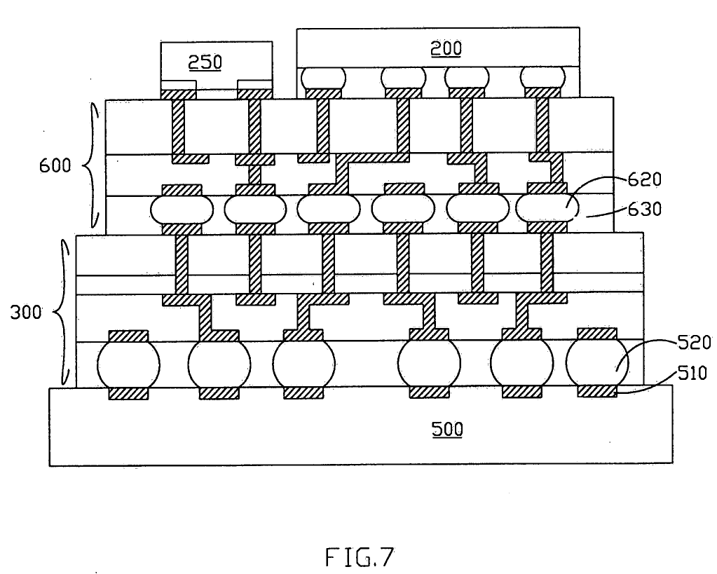

Referring to FIG. 7, the high-density multichip module structure is bonded to a package substrate according to a second embodiment of this invention. The passive chip 250 and the active chip 200 are separately bonded and stacked on the backside of an integrated circuit chip 600. The chip 600 is flipped and mounted on a multichip module substrate 300 (as shown in FIG. 4) via bumps 620, and an underfill material 630 is applied to protect the bumps 620 to form a multichip module with three integrated circuit chips 200, 600 and 300 and a passive chip 250. The chips in the high-density multichip module are stacked and electrically connected by a three-dimensional face-to-back interconnection so as to upgrade signal transmission performance between these chips. The numbers of stack levels and chips are not limited to this embodiment. The high-density multichip module structure can also bond to a package substrate 500 or bond to another multichip module structure by flip chip packaging according to various applications.

Other embodiments of the invention will appear to those skilled in the art from consideration of the specification and practice of the invention disclosed herein. It is intended that the specification and examples to be considered as exemplary only, with a true scope and spirit of the invention being indicated by the following claims.

What is claim is:

1. A multichip module structure, at least comprising:
a first multichip module substrate, comprising:
an semiconductor substrate having a first surface and a second surface;
an insulating layer being on said first surface;
a multilayer interconnection structure being on said insulating layer and having a third surface having a plurality of first bonding pads and a fourth surface having a plurality of second bonding pads and contacting said insulating layer;
a plurality of conductive plugs penetrating said semiconductor substrate and said insulating layer and electrically connecting to said second bonding pads respectively;
a plurality of third bonding pads being on said second surface and connecting to said conductive plugs respectively; and
a plurality of chips being on said second surface and electrically connecting to said third bonding pads.

2. The multichip module structure according to claim 1, wherein said multilayer interconnection structure includes at least one integrated circuit device.

3. The multichip module structure according to claim 1, wherein said semiconductor substrate has a thickness between 10 to 500 micron meter.

4. The multichip module structure according to claim 1, wherein said chip is an active chip.

5. The multichip module structure according to claim 4, wherein said active chip is mounted on said second surface by flip-chip type.

6. The multichip module structure according to claim 1, wherein said chip is a passive chip.

7. The multichip module structure according to claim 1, wherein said chips individually and electrically connect to said third bonding pads.

8. The multichip module structure according to claim 1, wherein said chips comprise a first active chip mounted on said first multichip module substrate by flip-chip type, and at least one chip electrically connecting and stacking on a backside of a first active chip.

9. The multichip module structure according to claim 8, wherein said at least one chip comprises a second active chip mounted on said backside of said first active chip by flip-chip type.

10. The multichip module structure according to claim 8, wherein said at least one chip comprises a passive chip.

11. The multichip module structure according to claim 1, further comprising a second multichip module substrate on said third surface, wherein said second multichip module substrate has a same structure as said first multichip module substrate.

12. The multichip module structure according to claim 1, wherein said multichip module structure is further electrically connected with a circuit board on said third surface.

13. A method for forming a multichip module structure, said method comprising:
providing a semiconductor substrate having a first surface and a second surface;
forming an insulating layer on said first surface;
forming a multilayer interconnection structure on said insulating layer, said multilayer interconnection structure comprising a third surface having a plurality of first bonding pads and a fourth surface having a plurality of second bonding pads, and contacting said insulating layer;
forming a plurality of conductive holes penetrating said semiconductor substrate and said insulating layer and electrically connecting to said second bonding pads respectively;
forming a plurality of third bonding pads on said second surface, wherein each said third bonding pad connects to said conductive plugs respectively; and
mounting a plurality of chips on said second surface to electrically connect said third bonding pads.

14. The method according to claim 13, wherein said multilayer interconnection structure includes at least one integrated circuit device.

15. The method according to claim 13, further comprising a step of polishing said semiconductor substrate on said second surface to reduce a thickness of said semiconductor substrate to 10 to 500 micron meter.

16. The method according to claim 13, wherein said chip is an active chip.

17. The method according to claim 16, wherein said active chip is mounted on said second surface by flip-chip type.

18. The method according to claim 13, wherein said chip is a passive chip.

19. The method according to claim 13, wherein said chips individually and electrically connect to said third bonding pads.

20. The multichip module structure according to claim 13, wherein said chips comprise a first active chip mounted on said first multichip module substrate by flip-chip type, and at least one chip electrically connecting and stacking on a backside of a first active chip.

21. The method according to claim 20, wherein said at least one chip comprises a second active chip mounted on said backside of said first active chip by flip-chip type.

22. The method according to claim 20, wherein said at least one chip comprises a passive chip.

23. The method according to claim 13, further comprising mounting a circuit board on said third surface.

24. The method according to claim 13, further comprising mounting a second multichip module substrate on said third surface, wherein said second multichip module substrate has a same structure as said first multichip module substrate.
